(19) United States
(12) Patent Application Publication
(10) Pub. No.: US 2024/0037897 A1
(43) Pub. Date: Feb. 1, 2024

(54) FEATURE EXTRACTION METHOD FOR EXTRACTING FEATURE VECTORS FOR IDENTIFYING PATTERN OBJECTS

(71) Applicant: ASML NETHERLANDS B.V., Veldhoven (NL)

(72) Inventors: Danying LI, Shenzhen (CN); Meng LIU, Shenzhen (CN); Jen-Yi WUU, Sunnyvale, CA (US); Rencheng SUN, Shenzhen (CN); Cong WU, Shenzhen (CN); Dean XU, Shenzhen (CN)

(73) Assignee: ASML NETHERLANDS B.V., Veldhoven (NL)

(21) Appl. No.: 18/265,431

(22) PCT Filed: Nov. 24, 2021
(86) PCT No.: PCT/EP2021/082886

§ 371 Date: Jun. 5, 2023

(30) Foreign Application Priority Data
Dec. 21, 2020 (WO) PCT/CN2020/137977

(51) Int. Cl. G06V 10/44; G06T 7/11; G06V 10/764

(52) U.S. Cl. CPC G06V 10/44; G06T 7/11; G06V 10/764

(57) ABSTRACT

An apparatus and method of feature extraction for identifying a pattern. An improved method includes obtaining data representative of a pattern instance, dividing the pattern instance into a plurality of zones, determining a representative characteristic of a zone of the plurality of zones, generating a representation of the pattern instance using a feature vector, wherein the feature vector includes an element corresponding to the representative characteristic, wherein the representative characteristic is indicative of a spatial distribution of one or more features of the zone. The method may also include classifying and/or selecting pattern instances based on the feature vector.

### CROSS-REFERENCE TO RELATED APPLICATIONS

This application claims priority of PCT application PCT/CN2020/137977 which was filed on 21 Dec. 2020, and which is incorporated herein in its entirety by reference.

### TECHNICAL FIELD

The embodiments provided herein relate to pattern classification and selection technology, and more particular to pattern representation mechanisms for downstream pattern classification and selection for downstream processing.

### BACKGROUND

In manufacturing processes of integrated circuits (ICs), many techniques are utilized to improve the design and layout of IC circuits during manufacturing. IC manufacturers rely on selection, categorization, and classification of patterns for use in computational lithography tasks related to IC design. The ability to perform these tasks in computationally efficient ways is becoming increasingly important.

### SUMMARY

In some embodiments, a method of pattern representation by feature extraction comprises obtaining data representative of a pattern instance, dividing the pattern instance into a plurality of zones, determining a representative characteristic of a zone of the plurality of zones, generating a representation of the pattern instance using a feature vector, wherein the feature vector comprises an element corresponding to the representative characteristic, wherein the representative characteristic is indicative of a spatial distribution of one or more features of the zone. The method also comprises at least one of classifying or selecting pattern instances based on the feature vector. In some embodiments, the data representative of a pattern instance is layout data in Graphic Database System (GDS) format, Graphic Database System II (GDS II) format, Open Artwork System Interchange Standard (OASIS) format, or Caltech Intermediate Format (CIF). The method also comprises converting a feature into a representative point. The method further comprises determining an areal density of representative points in the zone of the plurality of zones. In some embodiments, the data representative of a pattern instance is image data. In some embodiments the image data is an inspection image, an aerial image, a mask image, an etch image or a resist image and the representative characteristic of the zone of the plurality of zones is one of a representative point count density or an image pixel density. In some embodiments, the method also comprises dividing the pattern instance using a concentric geometric shape.

In some embodiments, an system comprises a memory storing a set of instructions and at least one processor configured to execute the set of instructions to cause the apparatus to perform: obtaining data representative of a pattern instance, dividing the pattern instance into a plurality of zones, determining a representative characteristic of a zone of the plurality of zones, generating a representation of the pattern instance using a feature vector, wherein the feature vector comprises an element corresponding to the representative characteristic, wherein the representative characteristic is indicative of a spatial distribution of one or more features of the zone. The at least one processor is also configured to execute the set of instructions to cause the apparatus to further perform at least one of classifying or selecting pattern instances based on the feature vector. In some embodiments, the data representative of a pattern instance is layout data in Graphic Database System (GDS) format, Graphic Database System II (GDS II) format, Open Artwork System Interchange Standard (OASIS) format, or Caltech Intermediate Format (CIF). The at least one processor is also configured to execute the set of instructions to cause the apparatus to further perform converting a feature into a representative point. The at least one processor is also configured to execute the set of instructions to cause the apparatus to further perform determining an areal density of representative points in the zone of the plurality of zones. In some embodiments, the data representative of a pattern instance is image data. In some embodiments the image data is an inspection image, an aerial image, a mask image, an etch image, or a resist image and the representative characteristic of each zone is one of a point count or an image pixel density. The at least one processor is also configured to execute the set of instructions to cause the apparatus to further perform dividing the pattern instance using a concentric geometric shape.

In some embodiments, a non-transitory computer readable medium that stores a set of instructions that is executable by at least one processor of a computing device to cause the computing device to perform a method for feature extraction for identifying a pattern comprises obtaining data representative of a pattern instance, dividing the pattern instance into a plurality of zones, determining a representative characteristic of a zone of the plurality of zones, generating a representation of the pattern instance using a feature vector, wherein the feature vector comprises an element corresponding to the representative characteristic, wherein the representative characteristic is indicative of a spatial distribution of one or more features of the zone. The method also comprises at least one of classifying or selecting pattern instances based on the feature vector. In some embodiments, the data representative of a pattern instance is layout data in Graphic Database System (GDS) format, Graphic Database System II (GDS II) format, Open Artwork System Interchange Standard (OASIS) format, or Caltech Intermediate Format (CIF). The method also comprises converting a feature into a representative point. The method further comprises determining an areal density of representative points in the zone of the plurality of zones. In some embodiments, the data representative of a pattern instance is image data. In some embodiments the image data is an inspection image, an aerial image, a mask image, an etch image, or a resist image and the representative characteristic of each zone is one of a point count or an image pixel density. In some embodiments, the method also comprises dividing the pattern instance using a concentric geometric shape.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a block diagram of an exemplary system for modelling or simulating parts of a patterning process, consistent with embodiments of the present disclosure.

FIG. 3 is a block diagram of an exemplary system, consistent with embodiments of the present disclosure.

FIGS. 4A-4C are exemplary diagrams used for feature extraction, consistent with embodiments of the present disclosure.

FIG. 5A-5C are exemplary diagrams used for feature extraction, consistent with embodiments of the present disclosure.

FIG. 6 is a process flowchart representing an exemplary method for feature extraction, consistent with embodiments of the present disclosure.

FIG. 7 is a process flowchart representing an exemplary method for feature extraction, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Additionally, various embodiments directed to an inspection process disclosed herein are not intended to limit the disclosure. The embodiments disclosed herein are applicable to any technology involving identifying patterns on or related to a wafer or integrated circuit including, but not limited to, inspection and lithography systems.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

In modern charged-particle beam lithography systems, there are many methods and processes that can aid in reducing defects. These methods can be implemented at various stages throughout the design phase to prevent defects before they occur. Many of these systems rely on analyzing data captured from completed manufacturing processes through inspection. Processes to eliminate defects before they occur include creating data-based models for the different steps in the IC manufacturing processing. These design techniques can adjust an IC design to account for variances in the manufacturing process so that manufactured IC chips reflect the intended structure. They can also include identifying areas of an IC design that result in hotspots and areas of an IC design that are susceptible to higher numbers of defects during manufacturing.

Each of these techniques, as well as many others, for improving IC designs prior to manufacturing rely on extensive amounts of pattern data to build and train models that are used to analyze the IC designs. The pattern data can include the target IC designs or the pictures captured from inspecting those designs during manufacturing. As models become more complex and IC manufactures utilize advanced methods such as machine learning and neural networks to create these models, the computational complexity for generating the models also increases.

Because of this increased computational complexity and the need for enormous pattern data sets, some of these techniques are not always practical. Instead, some techniques can use a subset of the patterns. To be effective, this subset needs to be representative and provide good coverage of the patterns in the target design. Categorizing or selecting the pattern data, referred to as “pattern selection” or “pattern reduction,” is a critical aspect to allowing for efficient analysis or prediction of wafer behavior with reduced amount of data.

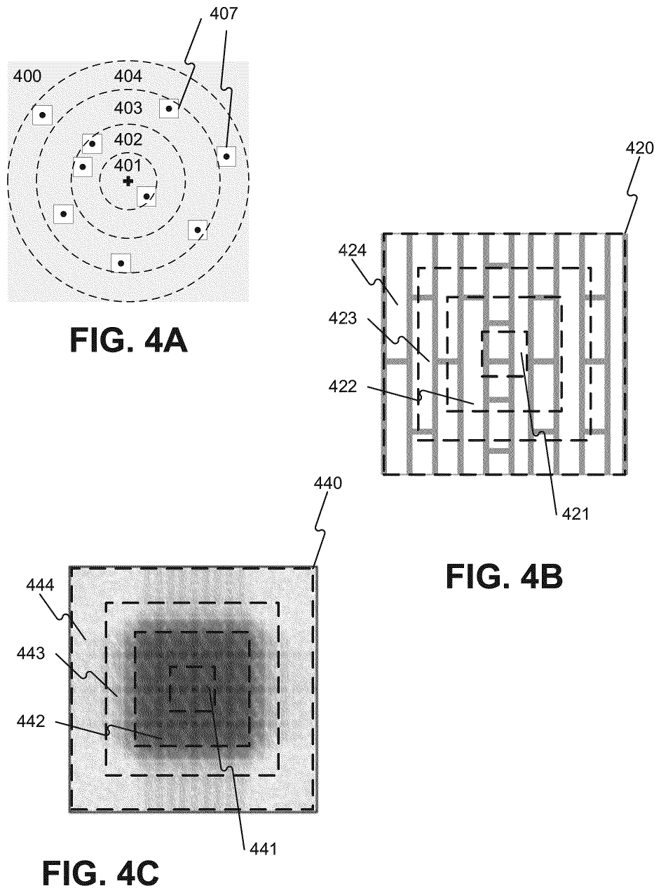

According to embodiments of the present disclosure, pattern selection can be improved by extracting information about specific features in a pattern and using those features to generate feature vectors (for example, as shown in FIGS. 4A-4C). The feature vectors can be generated by processing a design data stored in, for example, a GDS file (e.g., FIG. 4A) or from image data captured during inspection (e.g., FIG. 4B). However, the present disclosure is not limited to any specific form of pattern data, or any means of acquiring the pattern data. Additionally, inspection images can be processed or transformed before used for generating feature vectors based on different characteristics of a pattern (e.g., FIG. 4C). Different processes and algorithms can use the calculated feature vectors to computationally analyze and improve the lithography process without requiring intensive computations to analyze every pattern. Many downstream applications can utilize the pattern selection, classification, and categorization, consistent with the embodiments described herein, including machine learning based modeling or optical proximity correction (“OPC”), machine learning based defect inspection and prediction, source mask optimization (“SMO”) or any other technologies that can select representative patterns for reducing runtime and improving pattern coverage. Some applications intend to reduce the cycle time during standard iteration flow, which may benefit from this invention by applying a representative pattern set instead of full chip in some non-critical cycles.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

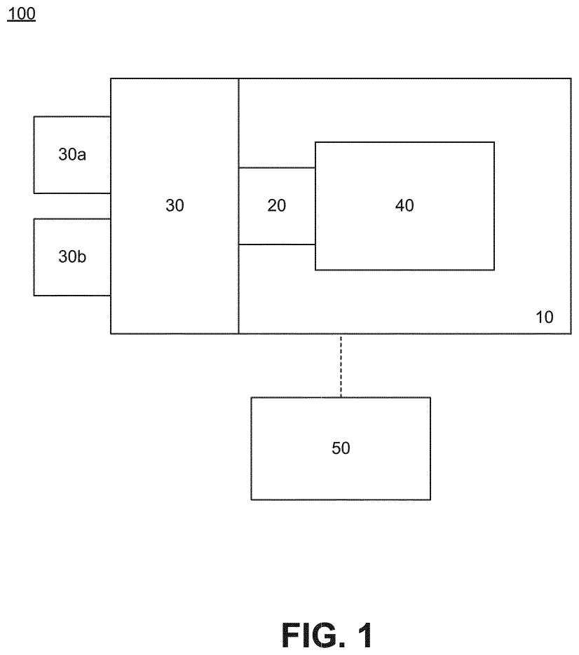

Reference is now made to FIG. 1, which illustrates an example electron beam inspection (EBI) system 100 consistent with embodiments of the present disclosure. As described below, the inspection system can generate pattern data. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

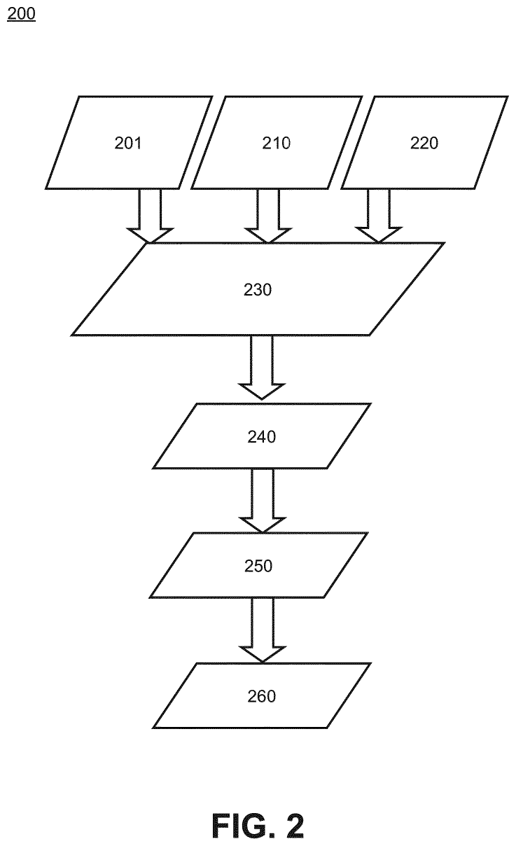

FIG. 2 is block diagram of an exemplary system 200 for modelling or simulating parts of a patterning process, consistent with embodiments of the present disclosure.

It is appreciated that the models used or created with system 200 can represent a different patterning process and need not comprise all the models described below. A source model 201 represents optical characteristics (including radiation intensity distribution, bandwidth and/or phase distribution) of the illumination of a patterning device. The source model 201 can represent the optical characteristics of the illumination that include, but not limited to, numerical aperture settings, illumination sigma (σ) settings as well as any particular illumination shape (e.g. off-axis radiation shape such as annular, quadrupole, dipole, etc.), where σ (or sigma) is outer radial extent of the illuminator.

A projection optics model 210 represents optical characteristics (including changes to the radiation intensity distribution or the phase distribution caused by the projection optics) of the projection optics. The projection optics model 210 can represent the optical characteristics of the projection optics, including aberration, distortion, one or more refractive indexes, one or more physical sizes, one or more physical dimensions, etc.

The patterning device/design layout model module 220 captures how the design features are laid out in the pattern of the patterning device and may include a representation of detailed physical properties of the patterning device, as described, for example, in U.S. Pat. No. 7,587,704, which is incorporated by reference in its entirety. In some embodiments, the patterning device/design layout model module 220 represents optical characteristics (including changes to the radiation intensity distribution or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 230 can be simulated from the source model 200, the projection optics model 210 and the patterning device/design layout model 220. An aerial image (AI) is the radiation intensity distribution at substrate level. Optical properties of the lithographic projection apparatus (e.g., properties of the illumination, the patterning device, and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 250 can be simulated from the aerial image 230 using a resist model 240. The resist model can be used to calculate the resist image from the aerial image, an example of which can be found in U.S. Pat. No. 8,200,468, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In some embodiments, the optical properties of the resist layer, e.g., refractive index, film thickness, propagation, and polarization effects—may be captured as part of the projection optics model 210.

The connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In some embodiments, the resist image can be used an input to a post-pattern transfer process model module 260. The post-pattern transfer process model 260 defines performance of one or more post-resist development processes (e.g., etch, development, etc.).

Simulation of the patterning process can, for example, predict contours, CDs, edge placement (e.g., edge placement error), etc. in the resist or etched image. Thus, the objective of the simulation is to accurately predict, for example, edge placement, aerial image intensity slope, or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDS II or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process. In order to effectively model the manufacturing process, system 200 can make use of efficient process, such as those disclosed herein, for pattern selection, categorization, and classification. Embodiments described below can provide feature vectors describing pattern instances for use with computational lithography models described in relation to FIG. 2.

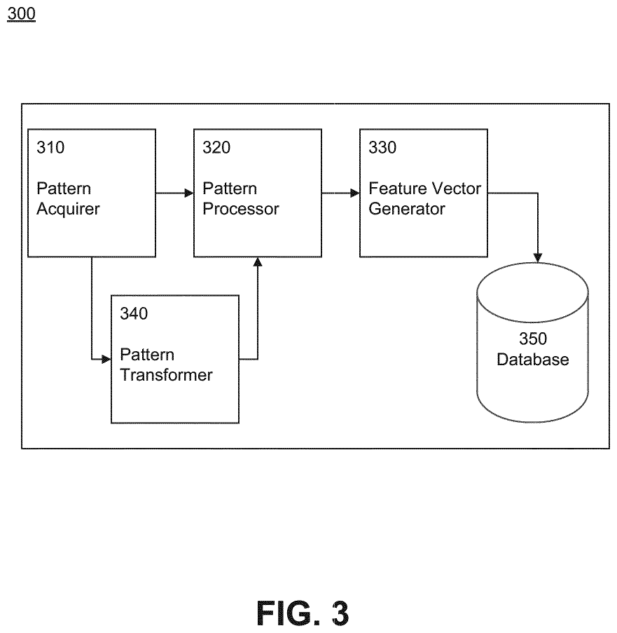

FIG. 3 is a block diagram of an exemplary system configured to perform feature extraction 300, consistent with embodiments of the present disclosure. It is appreciated that in various embodiments, system 300 may be part of or may be separate from a charged-particle beam inspection system (e.g., electron beam inspection system 100 of FIG. 1), patterning modeling, or computational lithography system (e.g., system 200 from FIG. 2), or other photolithography systems. In some embodiments, system 300 may be part of, for example, controller 50, patterning device/design layout model 220, part of other modules of FIGS. 1 and 2, implemented as part of a photolithography system, as a stand-alone apparatus or computer module, or as part of an electronic design automation system. In some embodiments, system 300 can include a pattern acquirer, pattern processor, feature vector generator, pattern transformer, a database, memory, storage, or the like.

As illustrated in FIG. 3 system 300 can include pattern acquirer 310, pattern processor 320, feature vector generator 330, pattern transformer 340, and database 350. According to embodiments of the present disclosure, pattern acquirer 310 can obtain a pattern associated with an IC design.

Pattern acquirer 310 can obtain a pattern representing all or a portion of an IC design layout used in, for example, system 200 of FIG. 2. Pattern acquirer 310 can obtain patterns in a variety of formats. In some embodiments, described in more detail in reference to FIG. 4A below, the patterns obtained by pattern acquirer 310 can be in a Graphic Database System (GDS) format, Graphic Database System II (GDS II) format, an Open Artwork System Interchange Standard (OASIS) format, a Caltech Intermediate Format (CIF), etc. The wafer design layout may include the patterns for inclusion on the wafer. The patterns may be mask patterns used to transfer features from the photolithography masks or reticles to a wafer. In some embodiments, a pattern in GDS or OASIS format, among others, may comprise feature information stored in a binary file format representing planar geometric shapes, text, and other information related to wafer design layout.

In some embodiments, described in more detail in reference to FIG. 4B below, the pattern obtained by pattern acquirer 310 can be an image or a portion of an image captured from inspecting a sample or wafer. For example, pattern acquirer 310 can obtain a pattern from an image generated by electron beam inspection system 100 in FIG. 1. In some embodiments, pattern acquirer 310 can obtain an image representing a pattern from a sample previously captured by a SEM or other inspection system (e.g., inspection system 100 of FIG. 1 or system 200 of FIG. 2). Pattern acquirer 310 can retrieve the pattern from a database, memory, or similar electrical component or storage. In some embodiments, the pattern obtained by pattern acquirer 310 can be a modified or transformed version of an image obtained through an inspection system (e.g., image 440 of FIG. 4C, described in more detail below). For example, the pattern can be all or part of an image of a sample that has undergone processing through, for example, a fast-Fourier transform (“FFT”) or a gaussian filter. It is appreciated that one of ordinary skill would be aware of other image transformations or manipulations that can be applied to inspection images or image-like objects or data structures. As demonstrated, pattern acquirer can obtain pattern information in a variety of formats allowing embodiments described herein to function across generic pattern information and formats and apply to a variety of practical applications and systems.

Pattern acquirer 310 can provide the pattern to pattern processor 320. Pattern processor 320 can prepare the pattern for generation of a feature vector. Pattern processor 320 can perform different processing based on the type of pattern received from pattern acquirer 310. Some of these differences are described in relation to embodiments corresponding to of FIGS. 4A-4C. FIGS. 4A, 4B, and 4C can represent, for example, a pattern in GDS format, in an unaltered inspection image format, and in a transformed image format, respectively. Pattern images can mask images, aerial images, resist images, or any other suitable pattern images that are well known in the art.

Referring to FIG. 4A, FIG. 4A is an exemplary pattern 400 that can be obtained from, for example, pattern acquirer 310. Pattern 400 can be a pattern stored in a GDS format. It is appreciated that pattern 400 is not limited to the GDS format but can be any similar data format or data structure representing layout information.

Pattern 400 can include various features located throughout the pattern. Features can be polygons of differing shapes that represent various components of a layout used to manufacture an IC. In some embodiments, the features can be reduced to corresponding representative points by using any suitable techniques, e.g., based on the geometry of the features. These feature representative points can be represented as feature points 407. The number of feature points 407 shown in FIG. 4A is exemplary. In some embodiments more features are present in pattern 400 and in some embodiments fewer feature points 407 are present in pattern 400. In some embodiments, the representative points may correspond to the centroid of the polygons for the features. The locations of the centroids can be determined based on the shape of the features. In some other embodiments, instead of using the centroid, a polygon can be represented by another coordinate, aspect, or another type of representative point of the features. For example, pattern processor 320 can use the first coordinate in the x- and y-dimension for the polygon, a shape representing the features, or a particular vertex that is part of the features

According to embodiments of the present disclosure, pattern processor 320 can process pattern 400 and divide pattern 400 into regions, areas, zones, or bins. In some embodiments, the bins can be represented as areas of concentric circles emanating outward from the center of pattern 400. For example, pattern processor 320 may divide pattern 400 into bins 401, 402, 403, and 404. Each bin covers a different portion of pattern 400.

Referring to FIG. 4B, FIG. 4B is an exemplary pattern 420 that can be obtained from, for example, pattern acquirer 310. Pattern 420 can be a pattern stored in an image format and represent part or all of an image captured during inspection of a sample by, for example, inspection system 100 or system 200. It is appreciated that pattern 420 can be stored in any suitable image format that can be processed or interpreted by pattern processor 320.

According to embodiments of the present disclosure, pattern processor 320 can process pattern 420 and divide pattern 420 into regions, areas, zones, or bins. In some embodiments, the bins can be represented as areas of concentric squares emanating outward from the center of pattern 420. For example, pattern processor 320 may divide pattern 420 into bins 421, 422, 423, and 424. Each bin covers a different portion of pattern 400.

Referring to FIG. 4C, FIG. 4C is an exemplary pattern 440 that can be obtained from, for example, pattern acquirer 310. Pattern 440 can be a pattern stored in an image format and represent part or all of an image captured during inspection of a sample by, for example, inspection system 100 or system 200, that has further been processed with an image transformation process. For example, pattern 440 can represent a pattern image that has been processed using an FFT. It is appreciated that pattern 440 can be stored in any suitable image format that can be processed or interpreted by pattern processor 320. Additionally, pattern 440 can be the result of a one or more image transformations including, but not limited to an FFT, a gaussian filter, or other image transformations well known in the art.

According to embodiments of the present disclosure, pattern processor 320 can process pattern 440 and divide pattern 440 into regions, areas, zones, or bins. In some embodiments, the bins can be represented as areas of concentric squares emanating outward from the center of pattern 420. For example, pattern processor 320 may divide pattern 440 into bins 441, 442, 443, and 444. Each bin covers a different portion of pattern 400.

Referring back to FIG. 3, pattern processor 320 can provide the processed patterns to feature vector generator 330. Feature vector generator 330 can use the processed patterns and convert the pattern, e.g., patterns 400, 420, and 440 into a feature vector. A feature vector can be a mathematical representation of the pattern. In some embodiments, the feature vector can be an n-tuple wherein each element in the feature vector can represent a characteristic of a bin of the pattern. The manner in which feature vector generator 330 determines each element of the tuple can depend on the nature of the pattern. Exemplary feature calculations are described in more detail in relation to FIGS. 4A-4C.

In some embodiments, a pattern is represented by a feature vector comprising feature densities or feature point density in the different bins. Referring again to FIG. 4A, feature vector generator 330 can, for example, calculate the areal density of the feature or feature points 407 by examining pattern 400 and bins 401, 402, 403, and 404. For example, feature vector generator 330 can determine that the centroid of one of the features 407 is located in bin 401. Feature vector generator 330 can also determine that 2 of the features 407 are located in bin 402, 4 of the features 407 are located in bin 403, and 2 of the features 407 are located in bin 404. From this information, the areal feature density of the feature or feature points in each bin can be calculated by dividing the number of feature or feature points in a bin by the area of that bin. For example, if the bins are chosen such that the area of bins 401, 402, 403, and 404 are 1, 3, 5, and 7 square units, respectively, then bins 401, 402, 403, and 404 have respective densities of 1, 0.667, 0.8, and 0.286. These densities can then be combined into a single feature vector, which can be represented as “(1, 0.667, 0.8, 0.286),” to represent the pattern.

In some embodiments, a metric other than areal feature density can be used to generate the feature vector. For example, feature vector generator 330 can calculate the total number of features or feature representative points in each bin, distribution of features or the feature representative points in each bin, or any other metric that can reduce the characteristics of the bin to a single value. Different characteristics of the pattern may be better suited for generating a feature vector depending on different applications. Feature vector generator 330 may be configured to determine the appropriate characteristic to use or can be configured based on the target application for the feature vectors.

In some embodiments, referring to FIGS. 4B and 4C, feature vector generator 330 can process pixels of the pattern images in the bins on pattern 420 or pattern 440 to determine a feature vector. For example, a grayscale image similar to that shown in pattern 420 and pattern 440 can contain pixel values, e.g., ranging from 0 to 255, with 0 being black, 255 being white and all other pixel intensities falling somewhere in between. In some embodiments, feature vector generator 330 can sum the pixel intensities of every pixel in a bin. In these embodiments, the sum for each bin can be used as the corresponding value in the feature vector. For example, the sum of the intensities in bin 421 or bin 441 can be the an element value of the feature vector for pattern 420 or 440 respectively. The pattern images can be captured or simulated SEM images, aerial images, resist images, mask images, or etch images, and etc.

It is appreciated that other aspects of the image pixels can be used to create the feature vector values. For example, instead of the sum of pixel intensities, feature vector generator 330 can use the average intensity, the maximum intensity, the minimum intensity, or some other characteristic of the data in a bin that can reduce that data to a single value. Different sources for the feature vector value can be better suited to different applications for the feature vector.

Referring back to FIG. 3, the feature vector created by feature vector generator 330 can be stored in database 350 for later use. In some embodiments, feature vector generator 330 can produce multiple feature vectors that can be stored in database 350. For example, these additional feature vectors can be feature vectors for different portions of the pattern, feature vectors created using different characteristics of the pattern, or feature vectors created with different bin sizes or layouts.

In some embodiments, pattern acquirer 310 can provide the pattern to pattern transformer 340 prior to processing the pattern. In these embodiments, pattern transformer 340 can apply a transformation or other image or file manipulation to the pattern prior to processing by pattern processor 320. For example, pattern transformer 340 can apply an FFT or gaussian filter to an image. Using a transformation, such as an FFT, can allow the pattern to be converted from a time-domain into a frequency domain and can allow additional flexibility and applications for the resulting feature vector.

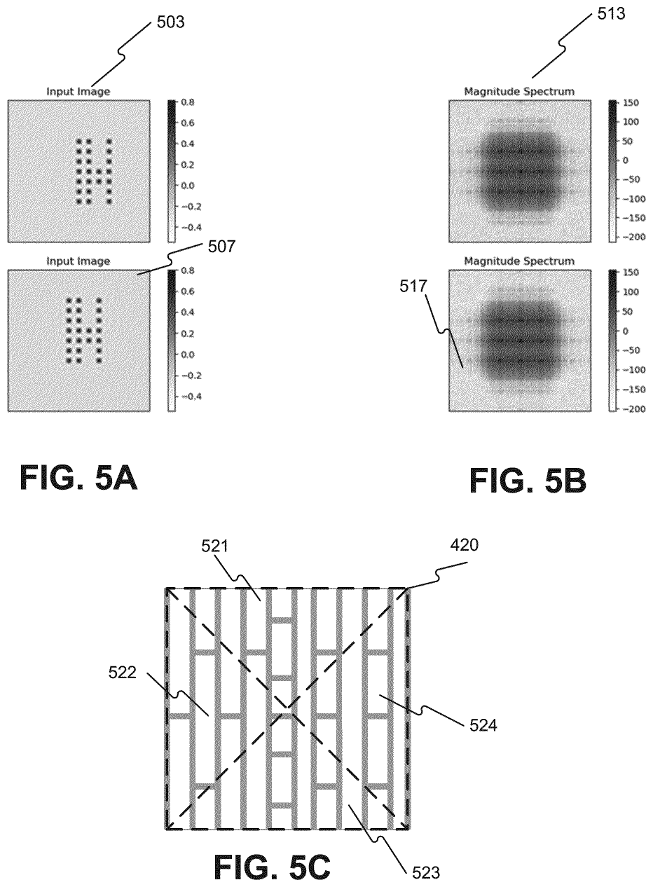

In some embodiments, using transformations can allow for additional flexibility when utilizing feature vectors for pattern matching. Referring to FIG. 5A and FIG. 5B, images 503 and 507 can represent features of a pattern that have the same geometry but have been shifted. When processing these images, pattern processor 320 may split the feature at different parts of the feature when calculating the bins. Accordingly, the spatial shift of the feature in the images can result in two different feature vectors for the same pattern. Images 513 and 517 represent the result of applying an FFT to input images 503 and 507, respectively. Because the FFT converts the image to a magnitude spectrum, the spatial shift in the images is avoided and the two features result in the same magnitude spectrum. Pattern transformer 340 can apply the FFT on images 503 and 507 and can provide the resulting images 513 and 517 to pattern processor 320. In this example, when processing images 513 and 517, pattern processor 320 can generate the same bins on the images and feature vector generator 330 can generate the same feature vector for the two input images 503 and 507 regardless of the spatial shift.

In some embodiments, an image acquired by pattern acquirer 310 may already have an image transformation applied. In other embodiments, pattern transformer 340 can apply a transformation to a pattern obtained by pattern acquirer 310 before processing by pattern processor 320. In some embodiments, pattern acquirer 310 can provide the same pattern directly to pattern processor 320 and also pattern transformer 340. In these embodiments, feature vectors can be generated, by feature vector generator 330, using both the original pattern and the transformed data files. In other embodiments, pattern processor 320 and feature vector generator 330 can operate on only the transformed data. Transforming a pattern can allow system 300 to generate feature vectors based on the transformed data and, as shown above, can result in the same feature vector for shifted patterns.

As described above, the interactions among various aspects of system 300 can result in different feature vectors generated from the same pattern. By adjusting the different components of system 300, different feature vectors can be produced for use in different applications. Additionally, different feature vectors from a single pattern can be used in combination with each other or can be used for different applications. Different processing techniques can be used to match the needs of the resulting application without needing complex modeling or computationally intensive algorithms to generate different feature vectors from the same patterns.

The feature vectors generated according to embodiments of the present disclosure can be used for pattern matching, such as exact matching or fuzzy matching. For example, feature vectors generated from different parts of layout can match even if the patterns used to generate those feature vectors are not exactly the same. By adjusting the bin size created by pattern processor 320, different levels of fuzziness can be introduced into the processing pipeline. For example, by increasing the bin size, the feature vector generated by feature vector generator 330 may be less precise. This could lead to patterns that do not have the exact same feature layout resulting in the same feature vector. But, in this example, the larger bin sizes can result in a smaller feature vector size that can improve processing efficiency.

The decreased precision in these embodiments can also benefit some applications. For example, when a layout is manufactured, the same component or feature may not be identical because of variances that occur during the manufacturing process. In this example, feature vectors generated by feature vector generator 330 for the sample may still match because the variances are accounted for by the fuzziness of the feature vector. In another example, a small number of bins can be used to generate a feature vector that can be used for prototyping of a particular process or application. In this example, more bins can then be efficiently applied to the original pattern to produce more precise feature vectors when moving beyond an initial prototype or planning phase.

In other embodiments, where higher precision is required, pattern processor 320 can use smaller bin sizes. Although this can result in larger feature vectors, the additional precision may be better suited for certain applications. Because of the flexibility inherent in system 300, the balance between precision and computational complexity can be tailored to different needs and different applications.

Differences in how pattern processor 320 lays out the bins on a pattern can also affect how the feature vectors are used. For example, for pattern 400 of FIG. 4A, pattern processor 320 can use concentric circles to generate bins 401, 402, 403, and 404. In some embodiments, instead of concentric circles, concentric squares are used such as is shown in FIGS. 4A and 4C. Each approach can be used to allow for uses in different applications. For example, if pattern processor 320 uses concentric circles to define the bins and feature vector generator 330 calculates a feature density-based feature vector, rotations in the pattern can result in the same feature vector. In these embodiments, a feature vector can be used to find the same or similar patterns throughout a wafer design or inspection image even if that patterns have different orientations throughout the design. Additionally, more complex combinations of bins can be utilized to further increase the effectiveness of the feature vector. For example, referring to FIG. 5C, pattern processor 320 can divide pattern 420 into non-concentric bins. As shown, pattern processor 320 can divide pattern 420 into 4 bins, such as bin 521, 522, 523, and 524, by drawing diagonal lines connecting the corners of pattern 420. The resulting bins can each represent a quadrant of pattern 420 with each bin being a rotation around the center of pattern 420 (i.e., bin 521 can be obtained by rotating bin 524 90°). Different bin sizes, numbers, and rotational angles can also be used. For example, bins rotated by 30°, 45°, 60°, 90°, or any other angle with corresponding number of bins can be used. By dividing pattern 420 in this way, the resulting feature vector, generated, for example, by feature vector generator 330, can be combined with a feature vector generated from the concentrically divided pattern 420 (e.g., as shown in FIG. 4B) to reduce the possibility that two different patterns reduce to the same feature vector. The feature vectors generated in this way can be used concurrently with the feature vector generated in relation to, for example, pattern 420 in FIG. 4B, or can be used separately.

Although the above disclosure discusses generating bins based on concentric shapes and or rotational quadrants, it is appreciated that one of ordinary skill in the art could apply additional combinations of bins (e.g., a grid or matrix). Although the feature vector generated from different types of bin creation may have different applications, advantages, and disadvantages, the process for applying the bins to the pattern and generating a feature vector from the individual bins remains the same as described in relation to system 300.

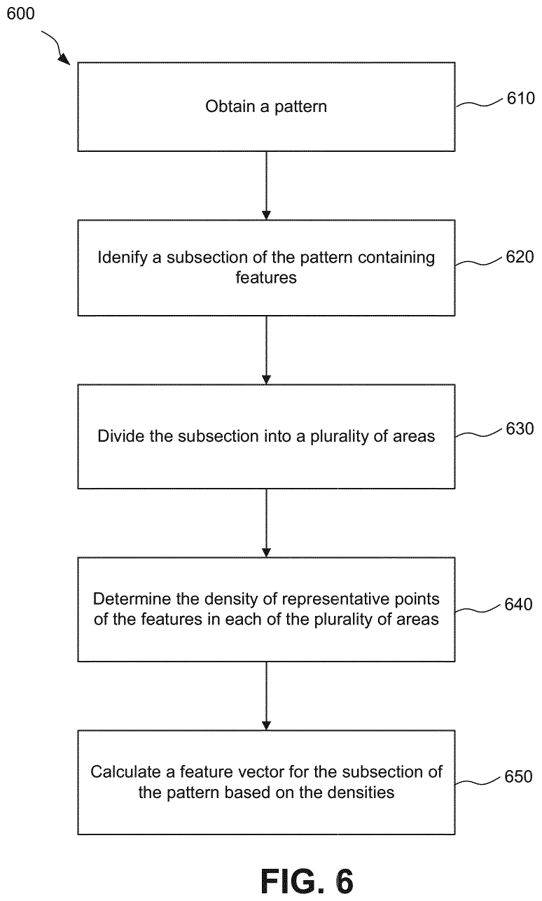

FIG. 6 is a process flowchart representing an exemplary method 600 for feature extraction, consistent with embodiments of the present disclosure. The steps of method 600 can be performed by system 300 of FIG. 3 executing on or otherwise using the features of a computing device, e.g., controller 50 of FIG. 1 for purposes of illustration. It is appreciated that the illustrated method 600 can be altered to modify the order of steps and to include additional steps.

In step 610, system 300 can obtain a pattern. The pattern can be a data file representing an IC design layout such as a GDS file or similar file or data structure (e.g., pattern 400 of FIG. 4A). The pattern can include polygon information related to features of an IC design, or pattern images of various types.

In step 620, system 300 can identify a subsection of the pattern that contains features (e.g., features 407 of FIG. 4A). In some embodiments, the identified features can be the same or similar features repeated throughout the pattern. In other embodiments, the identified features are all of the features in the pattern. At step 620, system 300 can identify the features and reduce the features to a point to represent the features. These feature representative points can be the centroid of the polygon representing the feature, a vertex of the polygon representing the feature, a representative point, or any other characteristic of the feature that identifies where the feature is located in the design.

In step 630, system 300 can divide the subsection of the pattern into a plurality of areas or bins. For example, system 300 can use concentric or non-concentric geometric shapes (e.g., circles) to define the boundaries of the different areas or bins (e.g., bins 401, 402, 403, and 404 of FIG. 4A). As described above, in some embodiments, different shapes or methods can be used to divide the pattern into bins (e.g., squares, circles, or other shapes can be used).

In step 640, system 300 can determine an indication of the feature density in each of the bins. For each bin created in step 630, system 300 can identify the number of features or feature representative points that are in the bin. In some embodiments, a feature can span multiple bins and be counted as occurring in both bins. In other embodiments, a feature that spans multiple bins can be considered to be located in a single bin based on the specific point or location used to identify the feature. After identifying the features or feature representative points in a bin, system 300 can determine the areal density of the bin by dividing the number of features or feature representative points by the area of the bin. As described above, in some embodiments, system 300 can utilize different methods of calculating a numerical value representing each bin.

In step 650, system 300 can calculate a feature vector representing the subsection of the pattern. System 300 can use the determined the density for each bin as an element of an n-tuple or vector. The combined densities can form a feature vector that can represent the subsection of the pattern. As constructed, matching patterns can result in matching feature vectors allowing for computationally efficient categorization and selection of patterns across an IC design.

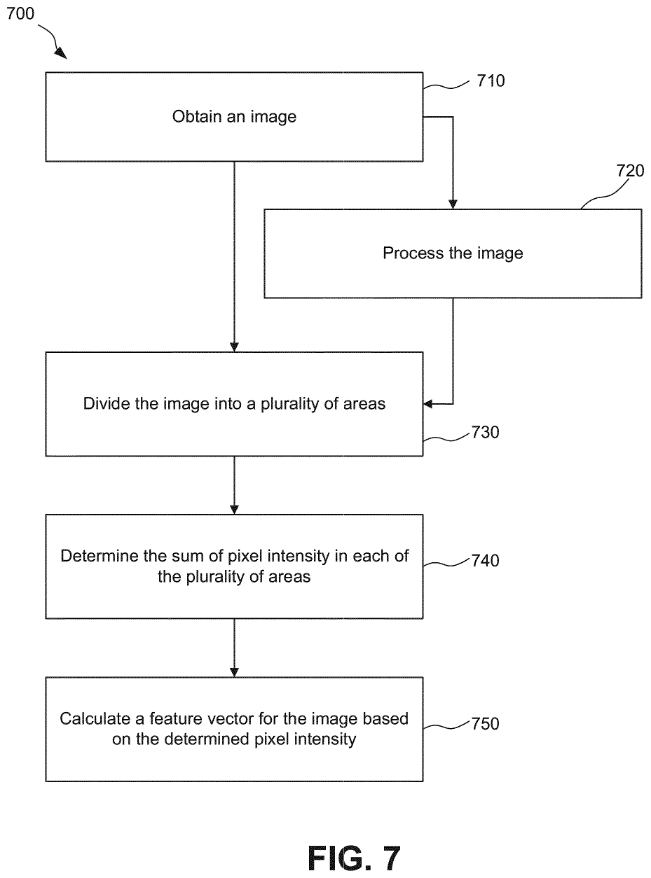

FIG. 7 is a process flowchart representing an exemplary method 700 for feature extraction, consistent with embodiments of the present disclosure. The steps of method 700 can be performed by system 300 of FIG. 3 executing on or otherwise using the features of a computing device, e.g., controller 50 of FIG. 1 for purposes of illustration. It is appreciated that the illustrated method 700 can be altered to modify the order of steps and to include additional steps.

In step 710, system 300 can obtain an image representing a pattern in an IC design. In some embodiments, the image can be an inspection image or portion of an inspection image of a sample as captured by, for example, inspection system 100 of FIG. 1 or obtained from system 200 of FIG. 2 (e.g., pattern 420 of FIG. 4B). In yet other embodiments, the image may be an inspection image or portion of an inspection image that has undergone image processing such an FFT or gaussian filter (e.g., pattern 440 of FIG. 4C). In some embodiments, the images can be simulated SEM images, or simulated aerial images, mask images, etch images, resist images, etc. In some embodiments, the obtained image will be further processed in step 720. In other embodiments, the method 700 continues directly at step 730. In some embodiments method 700 uses both a raw image (e.g., sending image directly to step 730 from 720 and can also further process the image in step 720. In these embodiments, method 700 can perform subsequent steps (e.g., steps 730, 740, and 750) on both images separately resulting in two feature vectors.

In step 720 system 300 can further process the image obtained in step 710. System 300 can apply filters or transformations to the obtained image. For example, system 300 can apply an FFT or gaussian filter to the image. (e.g., the transformation applied to images 503 and 507 to produce images 513 and 517 in FIGS. 5A and 5B). The particular transformation or processing applied to the image can depend on the particular application that is using method 700.

In step 730, system 300 can divide the image into a plurality of areas or bins. For example, system 300 can use concentric or non-concentric geometric shapes (e.g., squares) to define the boundaries of the different areas or bins (e.g., bins 421, 422, 423, and 424 of pattern 420 in FIG. 4B and bins 441, 442, 443, and 444 of image 440 in FIG. 4C). As described above, in some embodiments, different shapes or methods can be used to divide the pattern into bins (e.g., squares, circles, or other shapes can be used).

In step 740, system 300 can determine the pixel intensity in each of the bins. For each bin created in step 730, system 300 can process pixels of pattern images in the bins. For example, in a grayscale image the intensity of each pixel can be a value, e.g., ranging from 0 to 255, with 0 being black, 255 being white and all other pixel intensities falling somewhere in between. System 300 can determine the overall pixel intensity by summing the individual pixel intensities in the bin. As described above, in some embodiments, system 300 can utilize different methods of calculating a numerical value representing each bin.

In step 750, system 300 can calculate a feature vector representing the image. System 300 can use the determined pixel intensity for each bin as an element of an n-tuple or vector. The combined intensities can form a feature vector that can represent the image. As constructed, matching images can result in matching feature vectors allowing for computationally efficient categorization and selection of patterns across an IC design.

A non-transitory computer readable medium may be provided that stores instructions for a processor of a controller (e.g., controller 50 of FIG. 1) or of a system (e.g., system 300 of FIG. 3) to carry out, among other things, image inspection, image acquisition, image transformation, image processing, image comparison, stage positioning, beam focusing, electric field adjustment, beam bending, condenser lens adjusting, activating charged-particle source, and beam deflecting. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and

Erasable Programmable Read Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure can be further described by the following clauses:
1. A method of feature extraction for identifying a pattern comprising:
obtaining data representative of a pattern instance;
dividing the pattern instance into a plurality of zones;
determining a representative characteristic of a zone of the plurality of zones;
generating a representation of the pattern instance using a feature vector, wherein the feature vector comprises an element corresponding to the representative characteristic, wherein the representative characteristic is indicative of a spatial distribution of one or more features of the zone.
2. The method of clause 1, further comprising at least one of classifying or selecting pattern instances based on the feature vector.
3. The method of clause 1 or 2, wherein the data representative of a pattern instance is a layout file.
4. The method of clause 3, wherein the layout file is in Graphic Database System (GDS) format, Graphic Database System II (GDS II) format, Open Artwork System Interchange Standard (OASIS) format, or Caltech Intermediate Format (CIF).
5. The method of clause 3 or 4, wherein obtaining data representative of a pattern instance further comprises converting a feature into a representative point.
6. The method of clause 5, wherein determining the representative characteristic of a zone of the plurality of zones further comprises determining an areal density of representative points in the zone of the plurality of zones.
7. The method of clause 1 or 2, wherein the data representative of a pattern instance is image data
8. The method of clause 7, wherein the image data is an inspection image, an aerial image, a mask image, an etch image, or a resist image.
9. The method of clause 7 or 8, wherein the representative characteristic of the zone of the plurality of zones is one of a representative point count density or an image pixel density.
10. The method of any one of clauses 1-9, wherein dividing the pattern instance into a plurality of zones further comprises dividing the pattern instance using a concentric geometric shape.
11. The method of any one of clauses 1-10, wherein the feature vector is provided for use in at least one of modeling, optical proximity correction (OPC), defect inspection, defect prediction, or source mask optimization (SMO).
12. A system comprising:
a memory storing a set of instructions; and
at least one processor configured to execute the set of instructions to cause the apparatus to perform:
   obtaining data representative of a pattern instance;
   dividing the pattern instance into a plurality of zones;
   determining a representative characteristic of a zone of the plurality of zones;
   generating a representation of the pattern instance using a feature vector, wherein the feature vector comprises an element corresponding to the representative characteristic, wherein the representative characteristic is indicative of a spatial distribution of one or more features of the zone.
13. The system of clause 12, the at least one processor is configured to execute the set of instructions to cause the apparatus to further perform at least one of classifying or selecting pattern instances based on the feature vector.
14. The system of clause 12 or 13, wherein the data representative of a pattern instance is a layout file.
15. The system of clause 14, wherein the layout file is in Graphic Database System (GDS) format, Graphic Database System II (GDS II) format, Open Artwork System Interchange Standard (OASIS) format, or Caltech Intermediate Format (CIF).
16. The system of clause 14 or 15, the at least one processor is configured to execute the set of instructions to cause the apparatus to further perform converting a feature into a representative point.
17. The system of clause 16, the at least one processor is configured to execute the set of instructions to cause the apparatus to further perform determining an areal density of representative points in the zone of the plurality of zones.
18. The system of clause 12 or 13, wherein the data representative of a pattern instance is image data.
19. The system of clause 18, wherein the image data is an inspection image, an aerial image, a mask image, an etch image, or a resist image.
20. The system of clause 18 or 19, wherein the representative characteristic of the zone of the plurality of zones is one of a point count or an image pixel density.
21. The system of any one of clauses 12-20, the at least one processor is configured to execute the set of instructions to cause the apparatus to further perform dividing the pattern instance using a concentric geometric shape.
22. The system of any one of clauses 12-21, wherein the feature vector is provided for use in at least one of modeling, optical proximity correction (OPC), defect inspection, defect prediction, or source mask optimization (SMO).
23. A non-transitory computer readable medium that stores a set of instructions that is executable by at least one processor of a computing device to cause the computing device to perform a method of feature extraction for identifying a pattern, the method comprising:
obtaining data representative of a pattern instance;
dividing the pattern instance into a plurality of zones;
determining a representative characteristic of a zone of the plurality of zones;
generating a representation of the pattern instance using a feature vector, wherein the feature vector comprises an element corresponding to the representative characteristic, wherein the representative characteristic is indicative of a spatial distribution of one or more features of the zone.
24. The non-transitory computer readable medium of clause 23, the set of instructions that is executable by at least one processor of the computing device to cause the computing device to further perform at least one of classifying or selecting pattern instances based on the feature vector.
25. The non-transitory computer readable medium of clause 23 or 24, wherein the data representative of a pattern instance is a layout file.
26. The non-transitory computer readable medium of clause 25, wherein the layout file is in Graphic Database System (GDS) format, Graphic Database System II (GDS II) format, Open Artwork System Interchange Standard (OASIS) format, or Caltech Intermediate Format (CIF).
27. The non-transitory computer readable medium of clause 25 or 26, the set of instructions that is executable by at least one processor of the computing device to cause the computing device to further perform converting a feature into a representative point.
28. The non-transitory computer readable medium of clause 27, the set of instructions that is executable by at least one processor of the computing device to cause the computing device to further perform determining an areal density of the representative point in the zone of the plurality of zones.
29. The non-transitory computer readable medium of clause 23 or 25, wherein the data representative of a pattern instance is image data.
30. The non-transitory computer readable medium of clause 29, wherein the image data is an inspection image, an aerial image, a mask image, an etch image, or a resist image.
31. The non-transitory computer readable medium of clause 29 or 30, wherein the representative characteristic of the zone of the plurality of zones is one of a point count or an image pixel.
32. The non-transitory computer readable medium of any clauses 23-31, the set of instructions that is executable by at least one processor of the computing device to cause the computing device to further perform dividing the pattern instance using a concentric geometric shape.
33. The non-transitory computer readable medium of any clauses 23-32, wherein the feature vector is provided for use in at least one of modeling, optical proximity correction (OPC), defect inspection, defect prediction, or source mask optimization (SMO).
34. The method of clause 7, wherein the feature vector comprises elements of a same number as the plurality of zones, wherein each element corresponds to an areal density in a respective zone.
35. The method of clause 5, wherein the representative point corresponds to a centroid of the feature.
36. The method of clause 7, wherein the obtaining the data comprises performing FFT on the image data.

The block diagrams in the figures illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, a segment, or a portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A non-transitory computer readable medium that stores a set of instructions that is executable by at least one processor of a computing device to cause the computing device to at least:
obtain data representative of a pattern instance;
divide the pattern instance into a plurality of zones;
determine a representative characteristic of a zone of the plurality of zones; and
generate a representation of the pattern instance using a feature vector, wherein the feature vector comprises an element corresponding to the representative characteristic, wherein the representative characteristic is indicative of a spatial distribution of one or more features of the zone.

2. The medium of claim 1, wherein the instructions are further configured to cause the at least one processor to classify and/or select pattern instances based on the feature vector.

3. The medium of claim 1, wherein the data representative of a pattern instance is layout data.

4. The medium of claim 3, wherein the layout data is in Graphic Database System (GDS) format, Graphic Database System II (GDS II) format, Open Artwork System Interchange Standard (OASIS) format, or Caltech Intermediate Format (CIF).

5. The medium of claim 1, wherein the instructions configured to cause the at least one processor to obtain data representative of a pattern instance are further configured to cause the at least one processor to convert a feature into a representative point.

6. The medium of claim 5, wherein the instructions configured to cause the at least one processor to determine the representative characteristic of a zone of the plurality of zones are further configured to cause the at least one processor to determine an areal density of representative points in the zone of the plurality of zones.

7. The medium of claim 1, wherein the data representative of a pattern instance is image data.

8. The medium of claim 7, wherein the image data is an inspection image, an aerial image, a mask image, an etch image, or a resist image.

9. The medium of claim 7, wherein the representative characteristic of the zone of the plurality of zones is a representative point count density.

10. The medium of claim 7, wherein the representative characteristic of the zone of the plurality of zones is an image pixel density.

11. The medium of claim 1, wherein the instructions configured to cause the at least one processor to divide the pattern instance into a plurality of zones are further configured to cause the at least one processor to divide the pattern instance using a concentric geometric shape.

12. The medium of claim 1, wherein the feature vector is provided for use in one or more selected from: modeling, optical proximity correction (OPC), defect inspection, defect prediction, or source mask optimization (SMO).

13. The medium of claim 1, wherein the feature vector comprises elements in a same number as the plurality of zones, wherein each element corresponds to an areal density in a respective zone.

14. The medium of claim 5, wherein the representative point corresponds to a centroid of the feature.

15. The medium of claim 7, wherein the instructions configured to cause the at least one processor to obtain the data are further configured to cause the at least one processor to perform FFT on the image data.

16. A method comprising:
obtaining data representative of a pattern instance;
dividing the pattern instance into a plurality of zones;
determining a representative characteristic of a zone of the plurality of zones; and
generating, by a hardware computer system, a representation of the pattern instance using a feature vector, wherein the feature vector comprises an element corresponding to the representative characteristic, wherein the representative characteristic is indicative of a spatial distribution of one or more features of the zone.

17. The method of claim 16, further comprising classifying and/or selecting pattern instances based on the feature vector.

18. The method of claim 16, wherein the data representative of a pattern instance is a layout file.

19. The method of claim 16, wherein obtaining data representative of a pattern instance further comprises converting a feature into a representative point.

20. The method of claim 19, wherein determining the representative characteristic of a zone of the plurality of zones further comprises determining an areal density of representative points in the zone of the plurality of zones.
